(19) United States
(12) Patent Application Publication
(10) Pub. No.: US 2007/0148950 A1
(43) Pub. Date: Jun. 28, 2007

(54) Object and bonding method thereof

(75) Inventors: Chi-Ming Cheng, Taoyuan Hsien (TW); Zheng-Ping Lan, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/640,290

(22) Filed: Dec. 18, 2006

(30) Foreign Application Priority Data
Dec. 23, 2005 (TW) 094145984

(51) Int. Cl. H01L 21/44

(52) U.S. Cl. 438/612

(57) ABSTRACT

A bonding method of an object having at least one pad on a surface of the object includes the steps of: putting a mask on the object, when the mask has at least one pattern corresponding to the pad; and printing to form a solder ball on the pad by a printing method.

### CROSS REFERENCE TO RELATED APPLICATIONS

This Non-provisional application claims priority under 35 U.S.C. §119(a) on Patent Application No(s). 094145984 filed in Taiwan, Republic of China on Dec. 23, 2005, the entire contents of which are hereby incorporated by reference.

### BACKGROUND OF THE INVENTION

1. Field of Invention

The invention relates to an object and a bonding method thereof. In particular, the invention pertains to an object with a solder ball and the bonding method thereof.

2. Related Art

Thanks to the advances in technology and in view of the requirements for compactness and lightness in electronic products, conventional dual in-line packaged (DIP) or quad flat packaged (QFP) chips cannot satisfy modem needs. There is a restriction on the number of pins in the above-mentioned chips. Moreover, their electrical properties and thermal conductivity are inferior. Therefore, ball grid array (BGA) packaged chips have become the trend. The pins of the BGA packaged chip are formed by several solder balls. Thus, the BGA packaged chip has better electrical properties and thermal conductivity.

With reference to FIG. 1, the conventional BGA packaged chip 1 has several pads 11, each of which has a solder ball 12 for electrical connection with a circuit board (not shown). Although the BGA packaged chip 1 has the above-mentioned advantages, it has to be heated to a specific temperature to melt the solder balls 12 before it will be taken off to be tested. If the BGA packaged chip 1 is not damaged, the problem of putting the solder balls 12 back onto the pads 11 is an important issue.

To solve this problem, a conventional method is to dispose solder balls 12 with specific size one by one on the pads 11 of the BGA packaged chip 1 manually. There is also an alternative manual bonding method (FIG. 2). First, the BGA packaged chip 1 is fixed on a tool J. It is then covered by a sieve M with several holes. The holes of the sieve M correspond to the position of the pads 11. The solder balls 12 are then disposed in the sieve M. Afterwards, the sieve M, BGA packaged chip 1, and the tool J are shaken sideways, so that the solder balls 12 are disposed on the pads 11 of the BGA packaged chip 1. A reflow process is performed for the solder balls 12 to be bonded on the pads 11. Finally, the BGA packaged chip 1 is taken out.

However, the manual bonding method outlined above has time-consumption, inhomogeneous bonding quality, and unsuitability for automation. To solve these problems, an automatic bonding device (FIG. 3) is provided in the prior art. A vacuum pump V sucks the solder balls 12 using its vacuum head K and disposes them on the pads 11 of the BGA packaged chip 1. Nevertheless, the vacuum head K often cannot lift all the solder balls 12, so that the BGA packaged chip 1 thus produced is useless.

There are other automatic bonding methods being proposed, such as the automatic bonding device in R.O.C. Pat No. 292,785. However, this method cannot take advantage of existing manufacturing equipment and inevitably increases the product cost. Moreover, the operations involved therein are too complicated.

Therefore, the invention provides an object and the bonding method thereof to solve the above-mentioned problems.

### SUMMARY OF THE INVENTION

In view of the foregoing, the invention is to provide an object and the bonding method thereof by printing to form solder balls for simplifying the production procedure, increasing the reliability of bonding, and reducing the equipment cost.

To achieve the above, the invention discloses a bonding method for an object, one surface of which has at least one pad. The method includes the steps of: disposing a mask having at least one pattern corresponding to the pad on the object; and printing to form a solder ball on the pad.

To achieve the above, the invention also discloses an object, which has a body, at least one pad, and at least one solder ball. The body has a surface, on which the pad is disposed. The solder ball is formed on the pad by printing.

As mentioned above, the object and the bonding method of the invention can utilize existing equipment to form a solder ball on a pad by printing. The invention can be applied to the bonding and reworking processes of the object for simplifying the production procedure, increasing the reliability of bonding, and reducing the equipment cost.

### BRIEF DESCRIPTION OF THE DRAWINGS

The invention will become more fully understood from the detailed description given herein below illustration only, and thus is not limitative of the present invention, and wherein:

FIG. 1 is a schematic view of a BGA packaged chip in the prior art;

FIG. 2 is a schematic view of a BGA packaged chip formed by manual bonding in the prior art;

FIG. 3 is a schematic view of the conventional automatic bonding device;

FIG. 4 is a schematic view of an object according to the preferred embodiment of the invention;

FIG. 5 is a flowchart of the disclosed bonding method for the object; and

FIGS. 6A to 6E are schematic views illustrating the implementation of the disclosed bonding method.

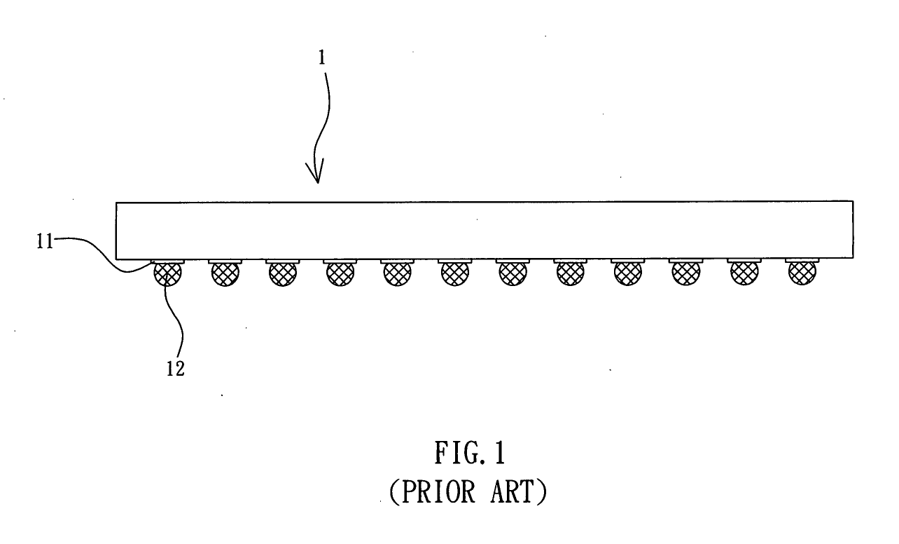

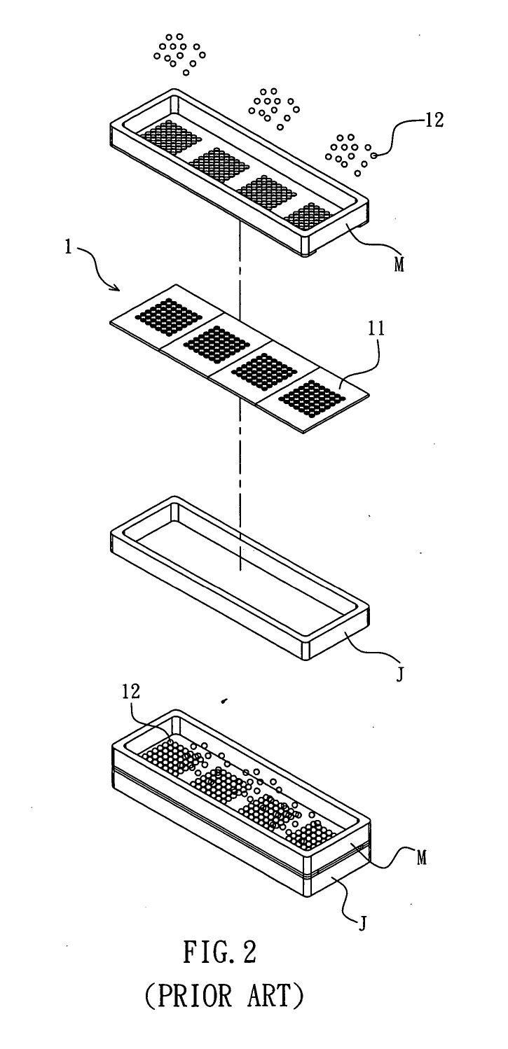

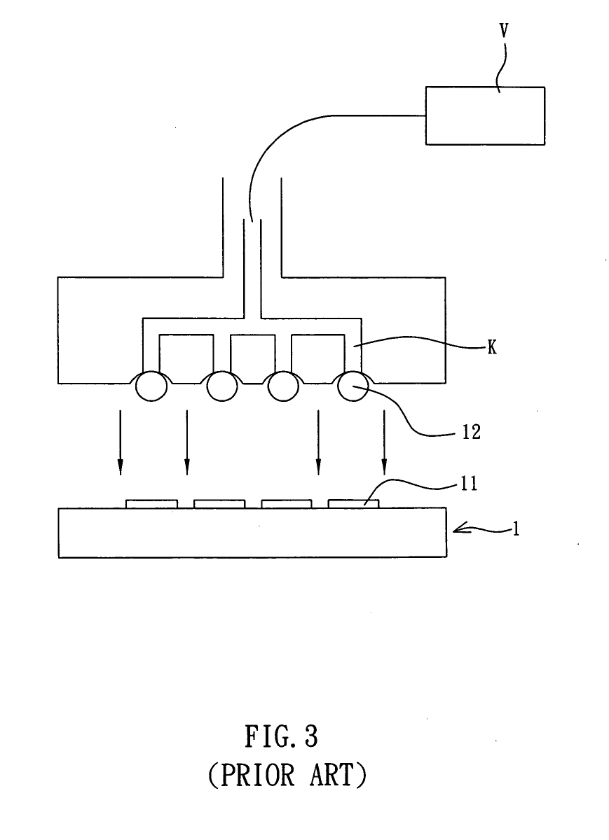

### DETAILED DESCRIPTION OF THE INVENTION

The present invention will be apparent from the following detailed description, which proceeds with reference to the accompanying drawings, wherein the same references relate to the same elements.

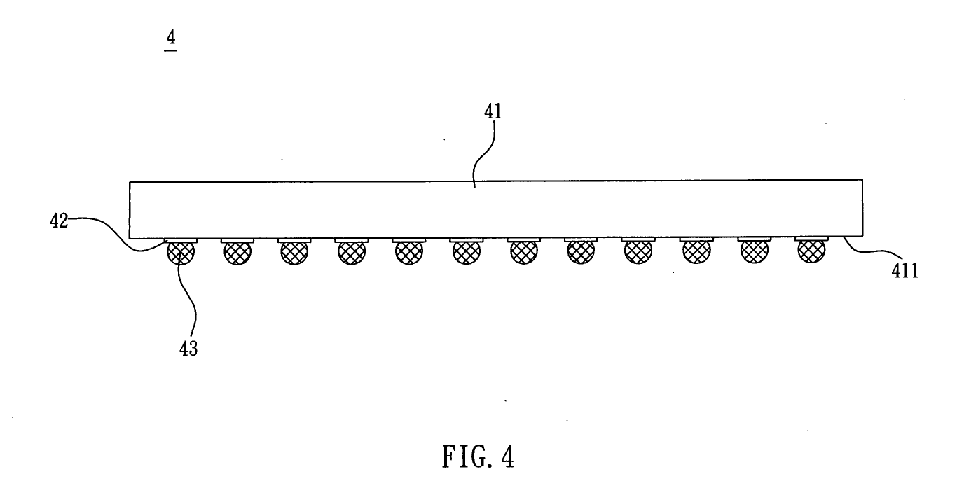

As shown in FIG. 4, an object 4 according to a preferred embodiment of the invention includes a body 41, at least one pad 42, and at least one solder ball 43. In this embodiment, the object 4 can be a ball grid array (BGA) package. However, the invention is not limited to this case. The object 4 can also be an electronic device, a semiconductor device, a chip, a package, a structure to be reworked, or any other object to be bonded. The body 41 has a surface 411.

The number of the pad 42 can be one, two or more than two. When the number of the pad 42 is not one, the pads 42 can be arranged on the surface 411 in an array. The material of the pads 42 can be copper, lead, aluminum, gold, silver, tin, bismuth, or their alloys.

The solder balls 43 are correspondingly formed on the pads 42 by printing (e.g., screen printing), so that each pad 42 is disposed with at least one solder ball 43. The material of the solder balls 43 can be copper, lead, aluminum, gold, silver, tin, bismuth, or their alloys.

The object 4 can be electrically coupled via the solder balls 43 to another electronic device, another semiconductor device, another chip, another package, and/or a circuit board (not shown) for transmitting signals.

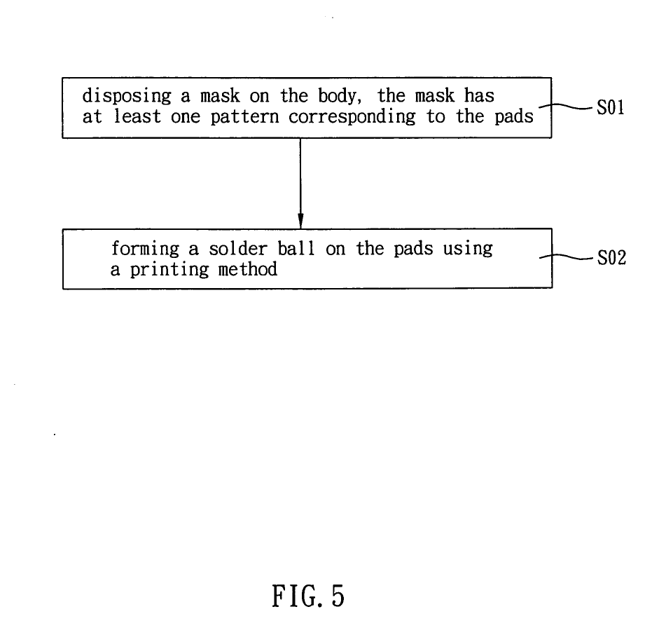

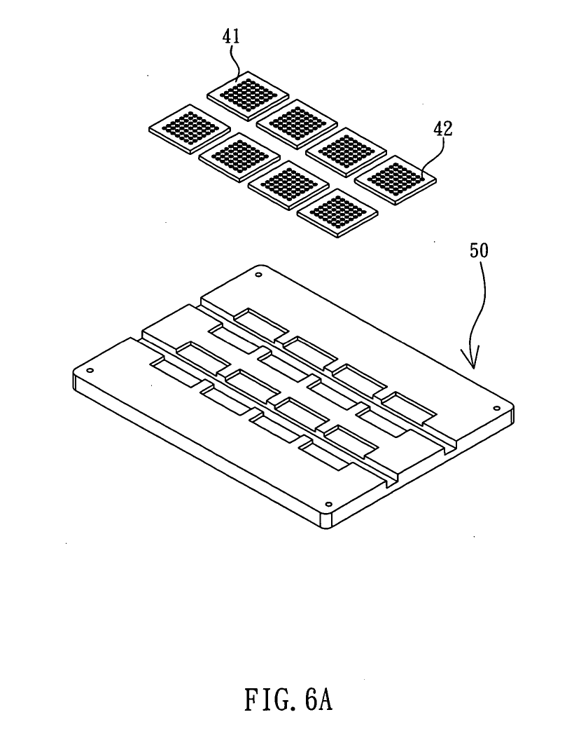

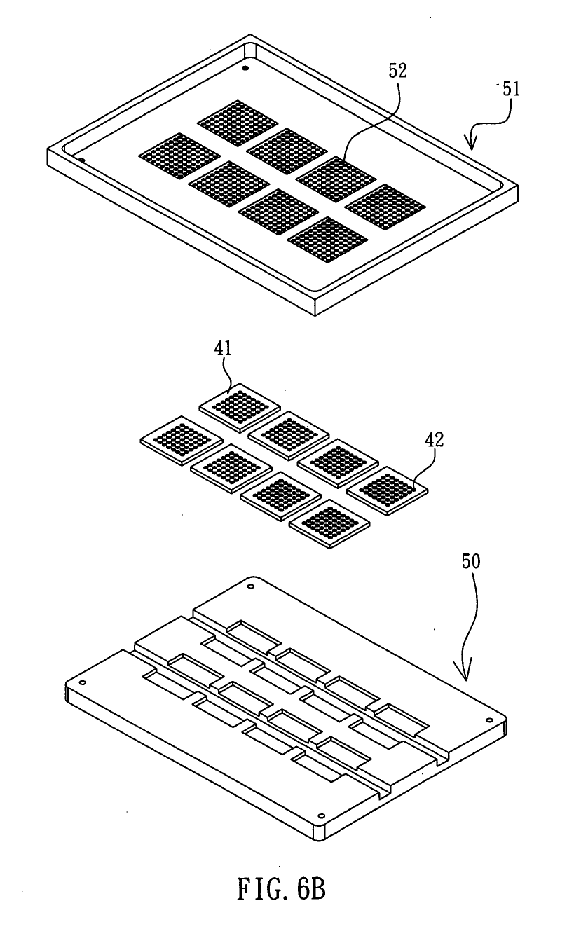

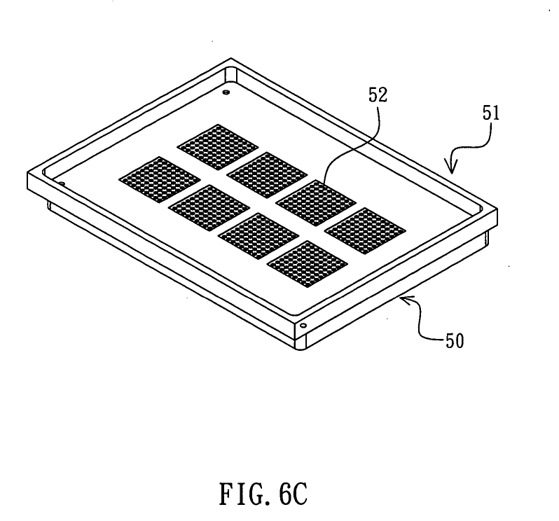

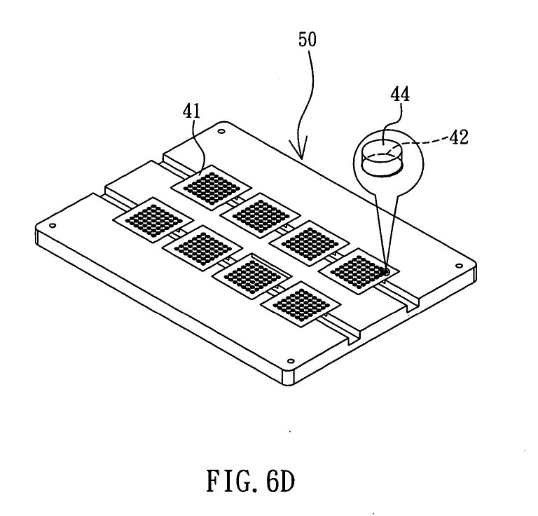

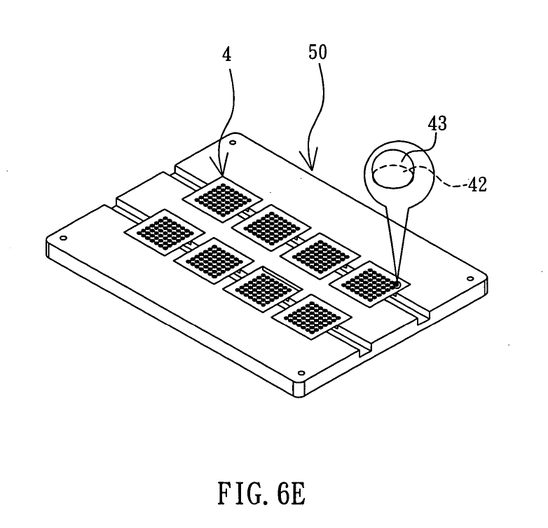

Please refer to FIG. 5 and FIGS. 6A to 6E for the flowchart of the disclosed bonding method for an object and schematic views of the object. The bonding method in this embodiment can be applied to form the object 4 in the last embodiment (schematically illustrated in FIG. 4). The surface 411 of the body 41 of the object 4 has several pads 42. The bonding method includes the steps of: disposing a mask with at least one pattern corresponding to the pads on the object; and printing to form a solder ball on each of the pads. First, as illustrated in FIG. 6A, a supporting base 50 holds and fixes the body 41. The body 41 can be fixed by pinching with a tool (not shown) or some other method.

Afterwards, as shown in FIGS. 5, 6B, and 6C, a mask 51 is disposed on the body 41 in step S01. The mask 51 has at least one pattern 52 corresponding to the pads 42. When the mask 51 is disposed on the body 41, the holes of the pattern 52 of the mask 51 is aligned to the pads 42. Herein, the pattern 52 may be an array of holes.

In step S02, a solder material is printed on the pads 42 to be a solder ball 43. The solder material may be copper, lead, aluminum, gold, silver, tin, bismuth, or their alloys. The solder material may include a soldering flux. In this embodiment, the solder material is a tin paste.

Afterwards, the mask 51 is removed. On each of the pads 42 a protrusion 44 (FIG. 6D) is formed. Finally, the supporting base 50 is disposed in a reflow furnace (not shown). The protrusions 44 on the body 41 are reflowed to evaporate the soldering flux therein. The protrusions 44 are formed as the solder balls 43 under the cohesive force of the solder material. As a result, each pad 42 has one solder ball 43. One thus obtains the bonded object 4 (FIG. 6E) after the body 41 is then taken out from the supporting base 50.

Suppose the object 4 should be reworked. One simply adds a step of removing existing solder balls on the object 4 before the above-mentioned procedure. One may even add a step of cleaning the surface 411 of the object 4, so that the surface of the pads 42 is essentially flat.

The disclosed bonding method only requires normal printing equipment for both bonding and reworking. Moreover, by re-designing the mask 51 and the supporting base 50 in the disclosed bonding method, bonding can be simultaneously performed for several objects 4. In comparison with the prior art, the disclosed bonding method has the advantages of simplifying the production procedure, increasing the reliability of bonding, and reducing the equipment cost.

Furthermore, when the solder material is in a melted state, one can simply fill the pattern 52 with the melted solder material, and the solder material is solidified to be protrusions 44. The mask 51 is removed afterwards.

The size of the solder balls 43 is controlled by adjusting the pattern size on the mask 51. Suppose the volume of the solder ball is X and the radius of the solder ball is R (i.e., the radius of the pattern 52), the thickness of the mask 51 is H, and the ratio of weight of the soldering flux to total weight of the solder material is Y. They satisfy the following relation: X=π×R²×H×(1−Y)×W, where (1−Y)×W is an adjusting parameter and W represents any environmental parameters to be adjusted according to needs. Moreover, the span between adjacent two holes in the pattern 52 is changed with the thickness H of the mask 51 and the radius R of the solder ball. It is preferably greater than or equal to 0.1 mm.

In summary, the object and the bonding method of the invention can utilize existing equipment to form a solder ball on a pad by printing. The invention can be applied to the bonding and reworking processes of the object for simplifying the production procedure, increasing the reliability of bonding, and reducing the equipment cost.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A bonding method of an object having a surface with at least one pad, the method comprising the steps of:
disposing a mask having at least one pattern corresponding to the pad on the object; and
printing to form a solder ball on the pad.

2. The bonding method of claim 1, wherein the step of printing to form a solder ball on the pad comprises the steps of:
printing to form a protrusion on the pad; and
performing a reflow to form the solder ball from the protrusion.

3. The bonding method of claim 2, wherein the step of printing to form a protrusion on the pad comprises the steps of:
filling the pattern with a melted solder material;
solidifying the solder material to form the protrusion; and
removing the mask.

4. The bonding method of claim 2, wherein the volume of the solder ball is equal to π×(radius of the pattern)²×(the thickness of the mask)×(an adjusting parameter).

5. The bonding method of claim 4, wherein the protrusion comprises a soldering flux, and the adjusting parameter is (1−a ratio of weight of the soldering flux of the protrusion to total weight of the protrusion)×(an environmental parameter).

6. The bonding method of claim 1, further comprising the step of cleaning the surface of the object.

7. The bonding method of claim 1, wherein the printing method is a screen printing method.

8. The bonding method of claim 1, further comprising the step of removing an existing solder ball on the object.

9. The bonding method of claim 1, further comprising the step of fixing the object by using a supporting base or a tool for holding the object.

10. The bonding method of claim 1, wherein the material of the solder ball is copper, lead, aluminum, gold, silver, tin, bismuth, or their alloys.

11. The bonding method of claim 1, wherein the material of the pad is copper, lead, aluminum, gold, silver, tin, bismuth, or their alloys.

12. The bonding method of claim 1, wherein the pads are arranged in an array.

13. An object comprising:
a body with one surface;
at least one pad disposed on the surface; and
at least one solder ball correspondingly formed on the pad by printing.

14. The object of claim 13, wherein the material of the solder ball or the pad is copper, lead, aluminum, gold, silver, tin, bismuth, or their alloys.

15. The object of claim 13, wherein the pads are arranged in an array.

16. The object of claim 13, wherein the object is an electronic device, a semiconductor device, a chip, a package, a Ball Grid Array (BGA) package or a structure to be reworked.

17. The object of claim 13, wherein the object is connected with an electronic device, a semiconductor device, a chip, a package, or a circuit board.

18. The object of claim 13, wherein a method for forming the solder ball comprises the steps of:
disposing a mask having at least one pattern corresponding to the pad on the body; printing to form a protrusion on the pad; and
performing a reflow to form the solder ball from the protrusion.

19. The object of claim 18, wherein the volume of the solder ball is equal to π×(radius of the pattern)²×(the thickness of the mask)×(an adjusting parameter), wherein the protrusion comprises a soldering flux, and the adjusting parameter is (1−a ratio of weight of the soldering flux of the protrusion to total weight of the protrusion)×(an environmental parameter).

20. The object of claim 18, wherein the pattern has at least one hole, and the span between adjacent two holes is at least 0.1 mm.
